(19) United States
(12) Patent Application Publication
(10) Pub. No.: US 2023/0307311 A1
(43) Pub. Date: Sep. 28, 2023

(54) SEMICONDUCTOR MODULE COMPRISING A HEAT SINK

(71) Applicant: Siemens Aktiengesellschaft, 80333 München (DE)

(72) Inventors: HUBERT SCHIERLING, Erlangen (DE); JENS SCHMENGER, Forchheim (DE)

(73) Assignee: Siemens Aktiengesellschaft, 80333 München (DE)

(21) Appl. No.: 18/023,030

(22) PCT Filed: Jun. 18, 2021
(86) PCT No.: PCT/EP2021/066540

§ 371 Date: Feb. 24, 2023

(30) Foreign Application Priority Data
Aug. 26, 2020 (EP) 20192898.3

(51) Int. Cl. H01L 23/367; H01L 21/48

(52) U.S. Cl. CPC H01L 23/3677; H01L 21/4871

(57) ABSTRACT

A heat sink includes a mounting surface for arrangement of a semiconductor element. The mounting surface is formed with an open groove. An electrical line is arranged at least in part in the groove and has a connection region for connection of the semiconductor element.

The invention relates to a heat sink having a mounting surface for arranging at least one semiconductor element, wherein at least one open groove is embodied in the mounting surface. The invention further relates to a semiconductor module for an electrical energy converter comprising a heat sink and a semiconductor element arranged on a mounting surface of the heat sink. Finally, the invention also relates to a method for producing a semiconductor module.

Heat sinks, semiconductor modules and methods for their production are extensively known from the prior art, so there is no need to furnish separate documentary evidence for this. Heat sinks and semiconductor modules are widely employed in the prior art in order to transform electrical energy in many different ways. Typically, the transformation of the electrical energy is accomplished by means of an energy converter, which may be embodied for example as a power inverter, AC/AC converter, DC/DC converter or the like. The power inverter is a form of energy converter which couples an intermediate DC link circuit to an AC voltage network for energy transmission purposes in order that electrical energy can be exchanged between the intermediate DC link circuit and the AC voltage network. For this purpose, it is generally provided that the energy converter has at least one switching element which interacts with electrical energy stores. The at least one switching element is usually formed by means of at least one semiconductor module which can comprise one or more semiconductor switching elements. An AC/AC converter, on the other hand, couples two AC voltage networks to one another. Furthermore, the energy converter can also be a DC/DC converter which couples two DC voltage networks to one another for energy transmission purposes.

The AC voltage network can be formed for example by an alternating voltage supply network or also an electrical machine, in particular a multiphase electrical machine. By controlling the at least one switching element by means of a control unit in a switching mode of operation it is possible to achieve the desired conversion function of the power converter or of the energy converter or of the AC/AC converter so that the desired drive function can be realized by means of the electrical machine.

For this purpose, the switching elements or semiconductor switching elements are usually driven in a switching mode of operation at a predefined high clock rate which is substantially greater than a frequency of at least one phase alternating-current voltage of the AC voltage network. The desired coupling for energy transmission can then be established by means of certain control methods, for example pulse width modulation (PWM) or the like. For this purpose, the control unit provides specific switching signals for the at least one switching element or each of the switching elements so that the at least one switching element or the switching elements can be driven in the desired manner in the switching mode of operation.

In normal operation per specification, it is evident that the switching elements, which are formed by semiconductor elements of the semiconductor modules, in particular in the manner of power modules, are subject to a high thermal load. The degree of loading is dependent on the converted power, the clock rate, a cooling effect, which is typically achieved by means of the heat sink, and possibly further effects.

The semiconductor element is an electronic component which serves to enable a predefined functionality to be realized within an electronic hardware circuit. For this purpose, the semiconductor module has at least one semiconductor element. The semiconductor module further comprises for this purpose one or more electrical connection contacts by means of which it can be electrically connected to an electronic hardware circuit.

The semiconductor module comprises at least the at least one semiconductor element, which provides the physical, in particular electrical, functionality of the semiconductor module. Typically, the semiconductor element is formed by means of a semiconductor crystal which is embodied by means of physical and/or chemical treatment in terms of its crystalline structure to enable a predefined functionality to be realized, Such a functionality may be provided for example as a transistor, a diode, a thyristor, combination circuits composed hereof, for example also with realization of passive electronic components such as electrical resistors, electrical capacitors and/or the like. The semiconductor element can thus realize the function of a transistor, for example a bipolar transistor, a field-effect transistor, in particular a metal-oxide semiconductor field-effect transistor (MOSFET), an insulated-gate bipolar transistor (IGBT) and/or the like. Furthermore, the semiconductor module can also realize a thyristor, for example a TRIAL, a gate turn-off thyristor (GTO) and/or the like. These functionalities can of course also be provided combined in virtually any desired manner by means of the semiconductor module, in particular in order to enable further supplementary functionalities to be provided.

The semiconductor element can for example realize a bipolar transistor which implements a freewheeling function by means of an additionally integrated diode when electrical voltage is applied in reverse to the transistor. The semiconductor element typically has a correspondingly embodied semiconductor chip which is mechanically connected via a substrate to a mounting and cooling plate of the semiconductor module. The cooling plate of the semiconductor module serves for being fastened to a heat sink or its mounting surface such that in normal operation per specification of the semiconductor module or of the at least one semiconductor element, accumulating heat can be dissipated via the heat sink.

Typically, a housing is also fastened to the cooling and mounting plate, which housing protects the at least one semiconductor element against external influencing factors and has electrical connection contacts which are electrically connected to corresponding contact surfaces for connecting the at least one semiconductor element. The connection contacts serve to establish an electrical connection to the hardware circuit. The connection contacts can be embodied in the manner of pins for connecting or mounting on a printed circuit board and/or also as screw or clamping connections which can be connected for example to busbars or the like.

A method for producing a power module unit, as well as a power module unit, a power supply and a frequency converter, are already known from EP 3 624 184 A1. In order to improve the cooling of the semiconductor elements, this teaching proposes to mount the substrate together with the power semiconductor directly onto a base plate in order to replace a material border between the base plate and the heat sink. This is intended to improve the thermal connection of the semiconductor to the heat sink. The connection is intended to be established by means of heating in a furnace. The teaching of EP 3 624 184 A1 therefore proposes to fasten cooling fins of the heat sink after the substrate has been secured in position in corresponding recesses of the base plate.

Furthermore, DE 10 2018 207 745 A1 discloses a heat sink and a heat sink assembly. This teaching is intended to provide a heat sink and a heat sink assembly which are capable of efficiently dissipating heat that is concentrated on a chip portion of a power semiconductor device module. The heat sink is intended to have a heat dissipation structure portion that has a higher thermal conductivity than that of a heat sink body and to dissipate the heat thereby.

Even if the prior art has basically proven its worth, disadvantages remain nonetheless.

Semiconductor modules that are embodied for large electrical currents, for example greater than e.g. 1 A, in particular greater than e.g. 10 A, generally have screw connections which are arranged as connection contacts on a housing of the semiconductor module. For example, metal rails can be connected as busbars or also threaded bolts made of metal to the screw connections to provide the electrical connection. At the same time, the semiconductor module is also embodied to be mounted on a printed circuit board, for which purpose corresponding terminal studs are provided which can be inserted into corresponding through-openings in the printed circuit board and soldered in place there or also press-fitted. This results in an assembly sequence for the circuit arrangement in which the semiconductor module is first connected to the printed circuit board by means of the terminal studs, the assembly formed as a result is turned and positioned over a heat sink. Next, the semiconductor module is screwed to the printed circuit board and the heat sink as well as to the threaded bolts or metal rails by means of the screw connections.

As a result of this procedure, in particular as a result of the many boreholes, especially those serving for screw fastening, a lot of printed circuit board surface area is taken up in the region of the semiconductor module. The resulting disadvantage is that it is necessary to reduce conductor track cross-sections on the printed circuit board, or to route conductor tracks inconveniently, and surface area for positioning electronic components is reduced.

One problem among others that manifests itself here is that the connection contacts, which are embodied in the manner of screw connections, are usually arranged at end faces of the semiconductor module or its housing. For construction reasons, this is also not possible otherwise in the prior art. The construction of semiconductor modules in the prior art only allows a contacting from a top side of the semiconductor module that is arranged opposite the cooling surface side. The available installation space in the region of the semiconductor module thus cannot be used for arranging further components.

The object underlying the invention is therefore to develop a heat sink, a semiconductor module and a method for their production to the effect that an electrical connection of the semiconductor module can be realized in a manner affording greater flexibility.

As the achievement of the object, a heat sink, a semiconductor module and a method according to the independent claims are proposed by means of the invention.

Advantageous developments will emerge based on features of the dependent claims.

With regard to a generic heat sink, it is proposed by means of the invention in particular that at least one electrical line having at least one connection region for connecting the at least one semiconductor element is arranged at least in part in the at least one groove.

With regard to a generic semiconductor module, it is proposed by means of the invention in particular that the heat sink is embodied according to the invention and the semiconductor element is connected to the at least one electrical line of the heat sink.

With regard to a generic method, it is proposed by means of the invention in particular that a heat sink having a mounting surface for arranging at least one semiconductor element and having at least one groove incorporated in the mounting surface is provided, the at least one semiconductor element is connected to the mounting surface, the at least one electrical line is inserted into the at least one groove, a frame comprising the at least one semiconductor element is arranged on the mounting surface, the at least one semiconductor element is connected to the at least one electrical line, and a potting compound is arranged in the frame.

The invention is based among other things on the idea that the heat sink is able at least to some extent to take on a line routing function, in particular in the region of the electrical lines to which large electrical currents are usually applied. At the same time, the heat sink can be at least partially integrated into the semiconductor module such that a compact structural unit can be provided as the semiconductor module in which the limitations present in the prior art in terms of the arrangement of the connection contacts of the semiconductor module can largely be avoided. The invention therefore enables a high degree of flexibility to be realized in the design of the semiconductor module in conjunction with the heat sink, such that the disadvantages described in the introduction can be overcome at least to some degree. Installation space can be saved into the bargain.

For this purpose, the heat sink provides the at least one electrical line incorporated at least partially, preferably completely, into the mounting surface such that the complex line routing according to the prior art can preferably be largely avoided, but at least reduced. The electrical line can be formed by a material having good electrical conductivity which is arranged in the groove. Preferably, the electrical line fills the at least one open groove substantially completely. It is particularly advantageously provided that the electrical line preferably makes thermally good conductive contact with groove walls in order thereby to be able at the same time to contribute also to the thermal conductivity of the heat sink, By arranging the at least one electrical line in the groove of the heat sink, there is therefore no need for the thermal properties of the heat sink to be significantly compromised. Rather, it is even possible to improve the thermal conductivity even further by means of a suitable material, for example if an electrical line having a material made of copper is incorporated into a heat sink consisting of an aluminum alloy. Alternatively or in addition, the electrical line can be realized with a smaller cross-sectional surface area and consequently at lower cost because the higher losses caused thereby in relation to the conducting of the electrical current can be dissipated by way of the heat sink.

The at least one electrical line has at least one connection region which serves for connecting the at least one semiconductor element. The connection of the semiconductor element to the connection region can be realized by means of bonding, direct contact, soldering, welding and/or the like. Furthermore, the at least one electrical line can of course also have further connection regions in order to enable further semiconductor elements and/or electronic components to be connected.

By means of the invention it is therefore possible to relocate at least one wiring plane at least partially into the heat sink, thereby also enabling connection contacts of the semiconductor module to be embodied at virtually any suitable points. The arrangement limitations present in the prior art can largely be avoided as a result.

By this means it is possible not only to achieve a significant improvement in the connection situation for the semiconductor module in conjunction with the heat sink, but also to realize a much more compact design of the semiconductor module.

Furthermore, an improvement in thermal conductivity can also be achieved by integrating at least a part of the heat sink into the semiconductor module because a substrate which carries the semiconductor element can be directly connected to the mounting surface of the heat sink, for example by means of soldering, adhesive bonding, welding and/or the like. As a result, there is also no longer any need to apply force directly on the semiconductor module due to a screwed fixing. Screwing points can consequently be avoided or arranged in an area that is remote from the at least one semiconductor element. This also enables the semiconductor module to be connected on a side other than its top side. Thus, the invention also simultaneously allows a direct contacting within the semiconductor module.

Generally, as well as a semiconductor crystal, which provides the corresponding functional element, the semiconductor element preferably also comprises a substrate to which the semiconductor crystal is joined, preferably by means of a material-to-material bond. The mechanical connection to the heat sink can be realized by way of the substrate, or via a substrate surface disposed opposite the crystal-side surface of the substrate for the semiconductor crystal. This connection too can be embodied as a material-to-material bond, for example by means of soldering, welding or the like.

The semiconductor module comprising the at least partially integrated heat sink can be produced by providing the heat sink with the mounting surface for arranging the at least one semiconductor element, at least one groove being incorporated in the mounting surface. The at least one semiconductor element is connected to the mounting surface, for example by being joined by means of soldering, welding, adhesive bonding or the like. The at least one electrical line is then inserted into the at least one groove. Depending on requirements, however, the electrical line can also be inserted into the groove before the semiconductor element is connected to the mounting surface. A frame comprising the at least one semiconductor element is then arranged on the mounting surface, for example adhesively bonded or the like. The at least one semiconductor element is connected to the at least one electrical line. Finally, a potting compound, for example epoxy or the like, is arranged in the frame. The connection of the semiconductor element to the electrical line can be realized by means of screwing, ultrasonic welding, bonding and/or the like.

According to one development, it is proposed that the connection region has at least one contact surface or a connection contact element. This enables a reliable contacting of the electrical line to be achieved. The contact surface can be embodied for example matched according to the contacting method. For example, it can be embodied to suit a bonding technique. Furthermore, the connection region can of course also have one or more connection contact elements which are suitable for establishing an electrical connection, for example a terminal, a screw-type terminal, a soldering post and/or the like. For the electrical contacting, it can be provided that the connection region is embodied accordingly. For example, if provision is made for realizing a connection by means of soldering, it can be provided that the connection region has a nickel layer or the like.

Preferably, the electrical line terminates at least partially flush with the mounting surface. This enables a uniform, substantially continuous mounting surface to be achieved. This permits the at least one semiconductor element to be arranged at least also in a region in which the electrical line is arranged in the groove. A further increase in flexibility can be achieved as a result.

According to one development, it is proposed that external dimensions of the at least one electrical line are embodied at least to some extent matched to internal dimensions of the at least one groove. This enables the electrical line to make contact with walls of the groove at least indirectly in order thus to be thermally coupled to the heat sink. Furthermore, it enables the electrical line to be arranged fixed in the groove such that basically there is no need for separate fastening means for fixing the line in the groove.

Preferably, the groove has an electrically insulating layer at its surface. The electrically insulating layer enables an electrical insulation to be established between the heat sink and the electrical line. This is advantageous in particular in the event that the electrical line is at a different electrical potential than the heat sink. However, an electrically insulating layer does not need to be provided if the material of the heat sink already possesses electrically insulating properties. An example of such a material is aluminum oxide.

negative impact on the cooling function of the heat sink, in particular when at the same time the at least one electrical line also provides good thermal conductivity.

With regard to the semiconductor module, it is further proposed that the semiconductor element is arranged at least in part in the region of the electrical line. This not only enables the connection situation for the semiconductor element to be improved but also allows additional flexibility to be achieved in relation to the arranging of the at least one semiconductor element on the mounting surface. Thus, it is possible for example to route the electrical line in the heat sink under the semiconductor element. This is particularly advantageous in order for example to enable crisscrossings of electrical lines to be avoided or reduced.

With regard to the production of the semiconductor module, it is further proposed that the heat sink be produced together with the at least one electrical line in an additive manufacturing process. This allows the at least one electrical line to be arranged in a highly flexible manner in the heat sink, below the mounting surface of the heat sink. In this way, crossovers of electrical ones can basically also be realized.

It is further proposed that firstly the at least one groove is incorporated into the heat sink and then the at least one electrical line is introduced by means of the additive manufacturing process. In this development, the heat sink is provided with the at least one groove in the first instance and only the at least one electrical line is introduced by means of the additive manufacturing process. This performance of the method proves particularly advantageous in terms of costs and flexibility. This is because there is no need for the entire heat sink to be fabricated by means of the additive manufacturing process. This enables the additive manufacturing process to be realized very simply and cost-effectively. For example, the groove can be incorporated into the heat sink by means of a chip-removing method.

It is furthermore proposed that a layer composed of an electrically insulating material is incorporated into the groove by means of the additive manufacturing process before the at least one electrical line is inserted into the at least one groove. The layer can be applied at least in part on walls of the groove. Preferably, the layer covers the walls of the at least one groove completely. Performing the method in this way permits the electrically insulating layer to be formed in a very specific and individually tailored manner. Installation space can be saved as a result, for example.

According to one development, it is proposed that the mounting surface be machined in order to form a single flat surface at least in the region in which the at least one semiconductor element is arranged. This enables a substantially homogeneous smooth surface to be achieved which permits a comprehensive freedom of arrangement with regard to the positioning of the at least one semiconductor element. A further improvement in flexibility can be achieved as a result.

The advantages and effects recited for the heat sink according to the invention of course apply equally also to the semiconductor element according to the invention as well as to the method according to the invention, and vice versa. In particular, therefore, device features can also be formulated so as to be applicable to the method, and vice versa.

The exemplary embodiments explained hereinbelow are preferred embodiments of the invention. The features and feature combinations recited in the description hereinabove and also the features and feature combinations cited in the following description of exemplary embodiments and/or shown in the figures alone can be used not only in the combination disclosed in a particular case but also in other combinations. Accordingly, embodiment variants are to be deemed as encompassed by the invention or as disclosed which are not shown explicitly in the It is furthermore proposed that the at least one electrical line has an electrically insulating layer. This enables the electrical line to have an electrical insulation also in a region which does not make contact with the groove or a wall of the groove. Obviously, a combination with the electrically insulating layer of the groove can also be provided.

It is further proposed that an electrical insulation element is arranged at least in part between the at least one groove and the at least one electrical line. The electrical insulation element can be a separate element which is arranged between the electrical line and the wall of the groove. The insulation element can be formed for example from a plastic, a ceramic material and/or the like having only a low electrical conductivity. This embodiment is suitable for example for applications in which a large electrical voltage is present between the electrical line and the heat sink, for example an electrical voltage of approx. 500 V or even more.

It is furthermore proposed that the insulation element and/or the electrically insulating layer terminates at least in part flush with the mounting surface. This ensures that the insulation element or the electrically insulating layer does not protrude beyond the mounting surface. The mounting surface can thus be reserved substantially in its entirety for the arrangement of the at least one semiconductor element and/or further electronic components.

According to one development, it is proposed that the insulation element and/or the electrically insulating layer is formed from a thermally highly conductive material. Such a material can include for example aluminum oxide, boron nitride or the like. This enables a good thermal coupling to be achieved between the at least one electrical line and the heat sink. In particular, the use of the electrical line for conducting heat can be improved. Accordingly, thanks to the at least one groove in the mounting surface of the heat sink, there is no need for a barrier to be created in relation to the thermal conductivity. As a result, the invention can largely avoid a figures and explained but which are derived and can be produced from the explained embodiments by means of separate feature combinations. The features, functions and/or effects presented with reference to the exemplary embodiments can, taken in isolation, in each case represent individual features, functions and/or effects of the invention which are to be considered independently of one another and which in each case also develop the invention independently of one another. The exemplary embodiments are therefore also intended to comprise combinations other than those in the explained embodiments. Furthermore, the described embodiments can also be supplemented by further of the already described features, functions and/or effects of the invention.

It is shown in:

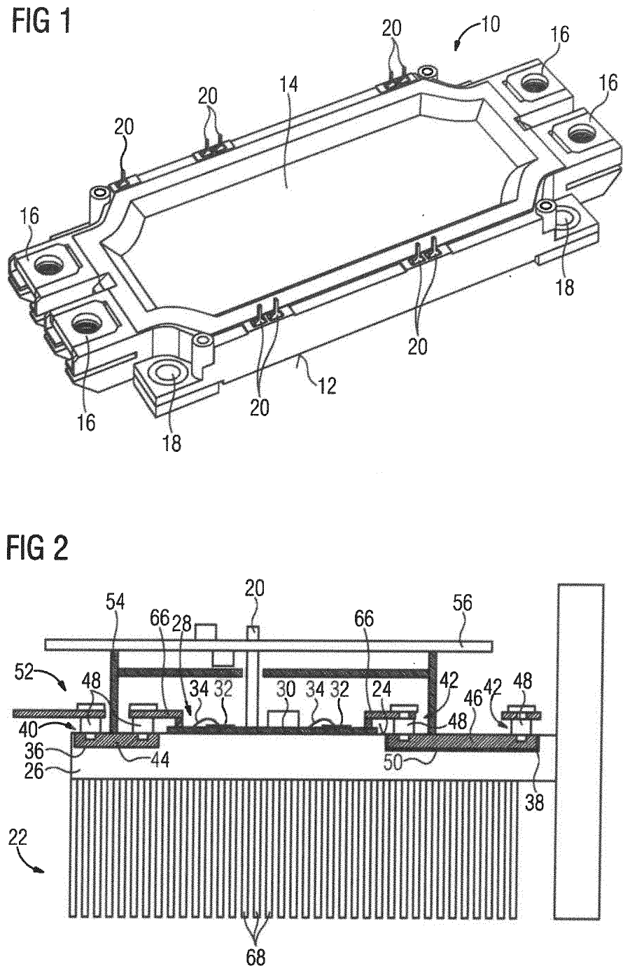

FIG. 1 a schematic perspective view of a semiconductor module according to the prior art,

FIG. 2 a schematic cross-sectional view of a semiconductor module comprising an integrated heat sink and electrical lines partially integrated into the heat sink,

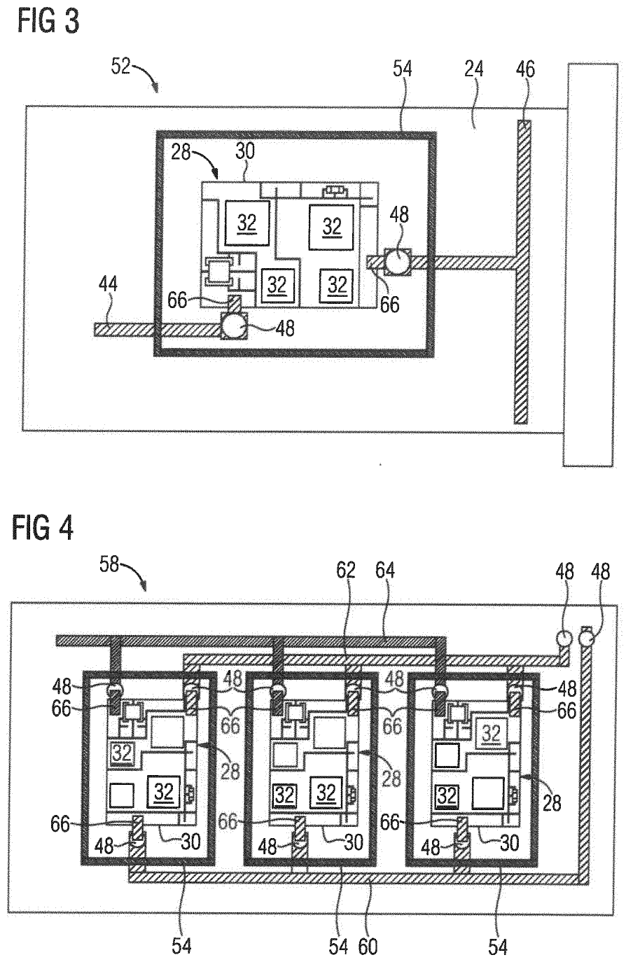

FIG. 3 a schematic plan view onto a mounting surface of the heat sink of the semiconductor module according to FIG. 2, and

FIG. 4 a further embodiment of a semiconductor module based on FIG. 3, but having three semiconductor elements.

FIG. 1 shows in a schematic perspective view a semiconductor module 10, also referred to as a power module, which serves for providing switching elements for a power inverter (not shown). The semiconductor module 10 comprises a cooling surface 12 which serves for connecting to a heat sink (not shown), specifically to its mounting surface.

The semiconductor module 10 further comprises a housing 14 which is mechanically connected to the cooling surface 12 and provides an interior space (not shown) in which a plurality of semiconductor elements (likewise not shown) are arranged and are thermally coupled to the cooling surface 12. The housing 14 is embodied substantially in the shape of a rectangle and provides, at its four corners, respective mounting sleeves 18 by means of which the semiconductor module 10 can be fastened to the heat sink as well as to a printed circuit board (not shown). A corresponding screw connection is provided for this purpose.

Opposite the cooling surface 12, there project from the housing 14 terminal lugs 20 which can be inserted into corresponding through-openings in the printed circuit board. In the present case, it is provided that said terminal lugs 20 are soldered in the corresponding through-openings of the printed circuit board. The terminal lugs 20 serve to provide corresponding control signals for the semiconductor module 10 as well as measurement signals that are necessary for its normal operation per specification.

At narrow opposite end faces of the housing 14, the housing 14 further comprises connection contacts 16 for large electrical currents, which contacts likewise provide a screw connection. Corresponding busbars can be connected to the connection contacts 16 by means of screw connections.

The embodiment according to FIG. 1 proves disadvantageous insofar as the connection contacts 16 essentially cannot be varied on account of the construction of the semiconductor module 10. As a result, a structuring of the power inverter is awkward to handle and can hardly be improved in terms of its construction.

FIG. 2 now shows a first embodiment of a semiconductor module 52 according to the invention by means of which the aforementioned disadvantages can largely be overcome. The semiconductor module 52 comprises a heat sink 22 which has a heat sink base plate 26 that has a mounting surface 24 on one side and cooling fins 68 on the opposite side. According to the teaching of EP 3 624 184 A1, the cooling fins can be incorporated and fastened subsequently, i.e. at the end of a production process of the semiconductor module 52, into grooves provided therefor.

As can be seen from the schematic cross-sectional view of the semiconductor module 52 according to FIG. 2, the mounting surface 24 serves for arranging a semiconductor element 28. The mounting surface 24 additionally has two open grooves 36, 38, Respective electrical lines 44, 46 are arranged in the grooves 36, 38. Each of the lines 44, 46 has a respective connection region 40, 42 which serves for the electrical connection of the respective electrical line 44, 46.

The heat sink 22 is formed in the present case from an aluminum ahoy. In alternative embodiments, a corresponding other material that is suitable for the intended application can also be used here. In particular, an electrically insulating material can of course also be used as the material for the heat sink, for example aluminum oxide or the like. The electrical lines 44, 46 are formed substantially from copper in the present example. In alternative embodiments, however, another suitable electrically conductive material can also be used here. For example, the material can be aluminum, an aluminum alloy, silver, a silver alloy and/or the like.

It can be seen from FIG. 2 that the electrical lines 44, 46 substantially fill out the respective grooves 36, 38 completely. Furthermore, the electrical lines 44, 46 terminate flush with the mounting surface 24. This enables a uniform, homogeneous, smooth, flat surface to be achieved, Basically, it is therefore also possible as a result to utilize the mounting surface 24 in the region of the respective grooves 36, 38.

In the present example, external dimensions of the electrical lines 44, 46 are embodied substantially matched completely to fit internal dimensions of the respective grooves 36, 38.

As can be seen from FIG. 2, the electrical line 44 makes contact with the heat sink base plate 26 of the heat sink 22 via the groove 36. In the present case, no electrical insulation is necessary here because both the heat sink and the electrical line 44 are at the same electrical potential.

In contrast, it is provided in the groove 38 that the groove 38 has an electrically insulating layer 50 on its surface. The electrically insulating layer 50 is produced in the present case by means of a galvanic layer which can be formed for example from aluminum oxide or the like. In the present case, the thickness of the electrically insulating layer 50 is suitably chosen such that it is able to provide adequate electrical insulation during normal, as-intended operation of the semiconductor module 52. This is because it is provided in this embodiment that the electrical line 46 is at a markedly different electrical potential than the heat sink 22, in particular its heat sink base plate 26.

Basically, it is of course also possible that the electrical lines 44, 46 themselves have an electrically insulating layer. This can of course also be combined with the electrically insulating layer 50. This enables an electrical insulation to be provided also on the mounting surface side. This is advantageous in particular when the region of the electrical lines 44, 46 is intended to be able to be used for arranging components.

Depending on requirements, it can of course also be provided in addition or alternatively that an electrical insulation element can be arranged between the respective electrical line 44, 46 and the respective groove 36, 38. The electrical insulation element can be a separately handleable component which can be arranged in the respective grooves 36, 38 before the electrical lines 44, 46 are inserted. The electrical insulation element can be for example a plastic part, a ceramic part or the like.

It is further provided in the present embodiment that the electrically insulating layer 50 terminates flush with the mounting surface 24, This affords a great degree of flexibility with regard to the mounting surface 24 because projections that protrude from the mounting surface 24 are avoided.

It can further be seen from FIG. 2 that the electrical lines 44, 46 have respective connection regions 40, 42 to which electrical terminal studs 48 are secured directly to the corresponding electrical ones 44, 46 by means of screw fastening.

A semiconductor element 28 is arranged in a center region of the mounting surface 24 which in the present case is kept free from the grooves 36, 38. The semiconductor element 28 comprises a substrate 30 on which semiconductor chips or semiconductor crystals 32 are fixed. In the present case, these are soldered onto the substrate 30. The semiconductor chips 32 are connected to electrical lines (not shown in FIG. 2) by means of bonding wires 34. The semiconductor element 28 is connected to respective terminal studs 48 via connecting lines 66. A screw connection is provided here in the present case. Additional fines can be connected to further terminal studs 48.

Furthermore, a terminal lug 20 is arranged on the semiconductor element 28, as has also already been explained with reference to FIG. 1, A corresponding control signal for the semiconductor switching elements provided by means of the semiconductor chips 32 can be provided via said terminal lug 20.

It can further be seen that the region of the semiconductor element 28 including the correspondingly assigned terminal studs 48 is surrounded by a frame 54. The frame 54 is fastened on the mounting surface 24, for example by means of adhesive bonding, welding or the like. In the present case, the frame 54 consists of a plastic. The frame is usually formed from an electrically insulating material.

The terminal lug 20 projects through the frame 54. In this embodiment, it is provided that the cavity provided by the frame 54 is filled with a potting material, for example epoxy. The semiconductor element 28 and its terminals are protected against external influencing factors as a result.

Even if it is provided in the present embodiment that the semiconductor element 28 is arranged outside the region of the electrical lines 44, 46, it can be provided that the mounting surface 24 is machined, for example by milling or the like, after the electrical lines 44, 46 are incorporated in order to form a single flat surface at least in the region in which the at least one semiconductor element 28 is arranged. This can also ensure that the semiconductor element 28 may in certain circumstances also be arranged in the region of at least one of the two electrical lines 44, 46. This enables a further degree of flexibility to be achieved by means of the invention.

FIG. 3 shows the semiconductor module 52 according to FIG. 2 in a schematic plan view. With regard to the details, reference is made to the previous detailed explanations.

It can further be seen in FIG. 2 that the terminal lug 20 projects through the printed circuit board 56 in a through-hole. This enables an electrical connection to be easily realized by soldering the terminal lug 20 in the corresponding via.

FIG. 4 shows a further semiconductor module 58 which is essentially based on the semiconductor module 52 according to FIGS. 2, 3. In contrast to the embodiment according to FIGS. 2 and 3, the semiconductor module 58 according to FIG. 4 has three semiconductor elements 28, each of which substantially corresponds to the semiconductor element 28 according to FIGS. 2 and 3.

It can be seen in FIG. 4 that an electrical line 62, which is likewise arranged in the heat sink 22, serves to supply a positive intermediate circuit potential of an intermediate DC link circuit. The electrical line 60, on the other hand, serves to supply a correspondingly negative intermediate circuit potential. The three semiconductor elements 28 are therefore connected in parallel to an intermediate DC link circuit (not designated any further). The further terminal studs 48 necessary for this are not shown in FIG. 4. In particular in the region of the frame 54, the electrical lines 60, 62, 64 are embodied as integrated into the heat sink 22. A corresponding outgoing feeder for providing an AC voltage can be achieved via the electrical line 64, which, arranged outside the frame 54, is not integrated into the heat sink 22 in the present case.

In the present embodiment, it is therefore provided that the three semiconductor elements 28 are connected substantially in parallel. This embodiment is therefore suitable for providing a switching element for a high-performance power inverter. It is further provided in this case that each semiconductor element 28 has its own frame 54, which is accordingly filled with potting compound. With regard to said further features of this embodiment, reference is additionally made to the statements made in relation to FIGS. 2 and 3.

By virtue of the construction according to the invention, in other words the incorporation of at least one wiring plane into a heat sink base plate 26, it is not only possible to achieve a considerable reduction in the installation space, but in addition it also allows a highly flexible arrangement of connection contacts such as the connection contacts 16 in FIG. 1. A considerable increase in flexibility can be achieved as a result.

As is clear from FIG. 2, this is because a printed circuit board 56 can be arranged directly opposite the heat sink 22 without any mounting holes needing to be provided for this purpose hi the printed circuit board. The use of the printed circuit board 56 can also be considerably improved as a result.

With regard to the method, it is provided in the present case that the heat sink 22 is firstly provided with its mounting surface 24 and with the grooves 36, 38, The semiconductor element 28 is then connected to the mounting surface 24 by soldering. Next, corresponding copper inlays for the electrical lines 44, 46 are inserted into the respective grooves 36, 38. For example, it can be provided that the copper inlays are free of insulation only in the vicinity of the connection regions 40, 42 and otherwise have an electrical insulation layer. For example, the copper inlays can be screwed in place by means of a clip. They are then fixedly connected to the heat sink 22 within the respective groove 36, 38.

The frame 54 encompassing the semiconductor element 28 is then adhesively bonded onto the mounting surface 24. The bonding agent can simultaneously serve to provide a sealing function, in particular in the region of the electrical lines 44, 46. The semiconductor element 28 can be connected to the electrical lines 44, 46 by means of a contacting device. This can be accomplished by means of screwing, ultrasonic welding and/or the like. Finally, a potting material is introduced into the frame 54. Accordingly, the semiconductor module 52 is now finished.

Alternatively or in addition, it can also be provided that the heat sink 22 is produced by means of an additive manufacturing method. For this purpose, the grooves 36, 38 are first milled into the heat sink 22, for example. The electrically insulating layer 50 can be produced by spraying on an insulation layer, for example by applying a ceramic material, by means of a coldspray method. Next, the material of the electrical lines 44, 46 can likewise be applied by means of a coldspray method. Finally, the mounting surface 24 can be face-milled and nickel-plated. The semiconductor element 28, in particular its substrate 30, can then be soldered onto the heat sink surface or mounting surface 24. Finally, the frame 54 is again adhesively bonded onto the mounting surface 24 in the region of the semiconductor element 28 and, as explained previously, the electrical contacting or electrical connection is realized. As a concluding step, potting material is also introduced into the frame 54 here.

The exemplary embodiments serve solely to explain the invention and are not intended to limit the same.

1.-16. (canceled)

17. A heat sink, comprising:
a mounting surface for arrangement of a semiconductor element, said mounting surface formed with an open groove; and
an electrical line at least in part arranged in the groove and comprising a connection region for connection of the semiconductor element.

18. The heat sink of claim 17, wherein the connection region includes a contact surface or a connection contact element.

19. The heat sink of claim 17, wherein the electrical line is designed to terminate at least partially flush with the mounting surface.

20. The heat sink of claim 17, wherein the electrical line has an external dimension which matches at least in part an internal dimension of the groove.

21. The heat sink of claim 17, further comprising an electrically insulating layer applied to a surface of the groove.

22. The heat sink of claim 17, wherein the electrical line comprises an electrically insulating layer.

23. The heat sink of claim 17, further comprising an electrical insulation element arranged at least in part between the groove and the electrical line.

24. The heat sink of claim 21, further comprising an electrical insulation element arranged at least in part between the groove and the electrical line wherein at least one of the electrical insulation element and the electrically insulating layer terminates at least partially flush with the mounting surface.

25. The heat sink of claim 21, further comprising an electrical insulation element arranged at least in part between the groove and the electrical line wherein at least one of the electrical insulation element and the electrically insulating layer is formed from a thermally high conductive material.

26. A semiconductor module for an electrical energy converter, said semiconductor module comprising:
a heat sink comprising a mounting surface formed with an open groove, and an electrical line at least in part arranged in the groove and comprising a connection region for connection of the semiconductor element; and
a semiconductor element arranged on the mounting surface of the heat sink connected to the electrical line of the heat sink.

27. The semiconductor module of claim 26, wherein the semiconductor element is arranged at least in part in a region of the electrical line.

28. A method for producing a semiconductor module, said method comprising:
connecting a semiconductor element to a mounting surface of a heat sink;
placing an electrical line in a groove of the mounting surface;
arranging a frame in surrounding relation to the semiconductor element on the mounting surface;
connecting the semiconductor element the electrical line; and
arranging a potting compound in the frame.

29. The method of claim 28, further comprising producing the heat sink together with the electrical line in an additive manufacturing process.

30. The method of claim 28, wherein the groove is incorporated into the heat sink before the electrical line is placed through an additive manufacturing process.

31. The method of claim 30, further comprising applying a layer composed of an electrically insulating material in the groove by the additive manufacturing process before the electrical line is placed in the groove.

32. The method of claim 28, further comprising machining the mounting surface to form a single flat surface at least in a region in which the semiconductor element is arranged.
